(19) United States
(12) Patent Application Publication
(10) Pub. No.: US 2024/0377751 A1
(43) Pub. Date: Nov. 14, 2024

(54) STRUCTURE INCLUDING SILICON GERMANIUM OXIDE PHOTORESIST UNDERLAYER AND METHOD OF FORMING SAME

(71) Applicant: ASM IP Holding B.V., Almere (NL)

(72) Inventors: João Ricardo Antunes Afonso, Tokyo (JP); Fanyong Ran, Tokyo (JP)

(21) Appl. No.: 18/659,735

(22) Filed: May 9, 2024

Related U.S. Application Data
(60) Provisional application No. 63/466,134, filed on May 12, 2023.

(51) Int. Cl. G03F 7/16; G03F 7/075

(52) U.S. Cl. CPC G03F 7/167; G03F 7/0755

(57) ABSTRACT

Methods of forming structures including a silicon germanium oxide photoresist underlayer and structures including the photoresist underlayer are disclosed. The methods can further include forming a passivation layer and/or an adhesion layer.

### CROSS-REFERENCE TO RELATED APPLICATIONS

This application claims priority to U.S. Provisional Patent Application Ser. No. 63/466,134 filed May 12, 2023 titled STRUCTURE INCLUDING SILICON GERMANIUM OXIDE PHOTORESIST UNDERLAYER AND METHOD OF FORMING SAME, the disclosure of which is hereby incorporated by reference in its entirety.

### FIELD OF INVENTION

The present disclosure generally relates to structures and to methods of forming structures. More particularly, the disclosure relates to structures including a photoresist underlayer and to methods of forming such structures.

### BACKGROUND OF THE DISCLOSURE

During the manufacture of electronic devices, fine patterns of features can be formed on a surface of a substrate by patterning the surface of the substrate and etching material from the substrate surface using, for example, gas-phase etching processes. As a density of devices on a substrate increases, it becomes increasingly desirable to form features with smaller dimensions.

Photoresist is often used to pattern a surface of a substrate prior to etching. A pattern can be formed in the photoresist by applying a layer of photoresist to a surface of the substrate, masking the surface of the photoresist, exposing the unmasked portions of the photoresist to radiation, such as ultraviolet light, and removing a portion (e.g., the unmasked or masked portion) of the photoresist, while leaving a portion of the photoresist on the substrate surface.

Extreme ultraviolet (EUV) lithography can provide relatively high resolution for smaller pitch patterns. However, such lithography generally uses a relatively thin photoresist film and a relatively thin carbon hard mask (CHM) film. Work on chemically amplified resists (CARs) has shown that thinner photoresist film induced an increase in line-edge and line-width roughness (LER/LWR).

Furthermore, scanners used for EUV lithography are generally expensive. Additionally, a relatively high dose of radiation is generally used for EUV applications, which can add to the expense associated with forming fine patterns and can reduce throughput. Yet further, EUV lamps can have a relatively short lifespan, which can also affect throughput and costs.

Accordingly, improved methods and structures suitable for forming fine patterns of features on a surface of a substrate are desired. For example, EUV techniques that can use lower doses of radiation are generally desirable.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to a method of forming a structure, and more particularly, to a method of forming a structure that includes a photoresist underlayer suitable for use with EUV. The underlayer can generate secondary electrons, which can reduce a dose of radiation used during a radiation exposure step, which can reduce costs and increase throughput associated with photoresist patterning steps.

While the ways in which various embodiments of the present disclosure address drawbacks of prior methods are discussed in more detail below, in general, various embodiments of the disclosure provide a method that includes forming a silicon germanium oxide underlayer. The inclusion of germanium in the photoresist underlayer can increase generation of secondary electrons during dosing, which can result in increased throughput and reduced costs. Further, dose reduction can be achieved without significantly affecting etch selectivity to an underlying layer.

In accordance with examples of the disclosure, a method of forming a structure comprising a photoresist underlayer includes providing a substrate comprising a substrate surface within a reaction chamber and forming a photoresist underlayer overlying the substrate surface. The photoresist underlayer can comprise silicon germanium oxide. The photoresist underlayer can be formed using a (e.g., first) cyclic deposition process. In accordance with examples of the disclosure, the method can further include forming a passivation layer between the substrate surface and the photoresist underlayer. In accordance with yet further examples of the disclosure, the method can include a step of forming an adhesion layer overlying and in contact with the photoresist underlayer. As set forth in more detail below, an amount of germanium in the silicon germanium oxide can be tuned based on the application. For example, when the photoresist is a chemical amplified resist and is used for forming patterns of lines, an amount of germanium in the silicon germanium oxide can range from about 1 to about 10 or from about 10 to about 60 at %. When the photoresist is used for forming holes or vias using a relatively thick photoresist layer (e.g., about 20 to about 60 or about 60 to about 200 nm thick), an amount of germanium in the silicon germanium oxide can range from about 1 to about 50 at %. A composition of the silicon germanium oxide can be as set forth above or as described below.

In accordance with additional exemplary embodiments of the disclosure, a structure is provided. The structure can be formed using, for example, a method as described herein. An exemplary structure includes a substrate, a photoresist underlayer comprising silicon germanium oxide overlying the substrate, and a photoresist layer overlying the photoresist underlayer. The substrate can include, for example, a carbon hard mask layer on a surface. In accordance with examples of the disclosure, the structure further comprises a passivation layer between the substrate surface (e.g., carbon hard mask layer) and the photoresist underlayer. In accordance with examples of the disclosure, a thickness of the photoresist underlayer can be greater than 0.1 nm and less than 10 nm. In accordance with further examples, a thickness of the adhesion layer is greater than 0 nm and less than 2 nm. In accordance with further examples, a thickness of the passivation layer is greater than 1 nm and less than 10 nm.

In accordance with further examples of the disclosure, a system for forming a structure, such as a structure described herein, is provided. Exemplary systems include a reaction chamber, a silicon precursor source fluidly coupled to the reaction chamber, a germanium precursor source fluidly coupled to the reaction chamber, an inert and/or reactant gas source fluidly coupled to the reaction chamber, and a controller configured to perform a method, such as a method described herein or a portion thereof.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a process of forming a passivation layer in accordance with exemplary embodiments of the disclosure.

FIG. 3 illustrates a process of forming a photoresist underlayer in accordance with exemplary embodiments of the disclosure.

FIG. 4 illustrates a process of forming an adhesion layer in accordance with exemplary embodiments of the disclosure.

FIG. 5 illustrates a structure in accordance with exemplary embodiments of the disclosure.

FIG. 6 illustrates a system configured for executing a method as described herein.

FIG. 7 illustrates a system in accordance with yet additional examples of the disclosure.

FIG. 8 illustrates dose reduction as a function of germanium concentration of structures in accordance with exemplary embodiments of the disclosure.

FIG. 9 illustrates normalized adhesion data versus CAR dose for structures in accordance with exemplary embodiments of the disclosure.

FIG. 10 illustrates germanium concentration versus dose reduction at various adhesion layer thicknesses for structures in accordance with exemplary embodiments of the disclosure.

FIG. 11 illustrates germanium concentration versus line width reduction for structures in accordance with exemplary embodiments of the disclosure.

FIG. 12 illustrates a collapse information for structures based on germanium concentration and adhesion layer thickness in accordance with exemplary embodiments of the disclosure.

FIGS. 13 and 14 illustrate scum that can form within vias.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood that the invention extends beyond the specifically disclosed embodiments and/or uses thereof and obvious modifications and equivalents thereof. Thus, it is intended that the scope of the invention disclosed should not be limited by the particular disclosed embodiments described below.

The present disclosure generally relates to methods of forming a structure that includes a silicon germanium oxide photoresist underlayer and to structures including a silicon germanium oxide photoresist underlayer. As described in more detail below, exemplary methods can be used to form structures suitable for use with or that include an EUV photoresist layer, such as a chemical amplified (CAR) photoresist layer. Use of a silicon germanium photoresist underlayer may be particularly desirable, because the silicon germanium photoresist underlayer can generate desired secondary electrons during EUV dosing, while maintaining desired etch selectivity. Further, use of a silicon germanium photoresist underlayer does not generate metal contamination that can otherwise occur with metal-based photoresist underlayers.

In accordance with further examples, the method includes forming a passivation layer. The passivation layer can mitigate material (e.g., carbon) loss of an underlying layer.

In accordance with yet further examples, the method additionally or alternatively includes forming an adhesion layer. Use of an adhesion layer as described herein can reduce defects that can otherwise occur during lithography processing. Further, surface energies of exemplary adhesion layers can be tuned (e.g., by changing process conditions during deposition of the adhesion layer) to promote adhesion between the photoresist underlayer and a layer of (e.g., EUV) photoresist.

As used herein, the term substrate may refer to any underlying material or materials including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can additionally or alternatively include various features, such as recesses, lines, and the like formed within or on at least a portion of a layer of the substrate. In accordance with examples of the disclosure, the substrate can include a carbon hard mask (CHM) on a surface.

In some embodiments, film refers to a layer extending in a direction perpendicular to a thickness direction. In some embodiments, layer refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous. In some cases, a layer may include a laminate structure of two or more materials.

In this disclosure, gas may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, and may include a seal gas, such as an inert gas.

In some cases, such as in the context of deposition of material, the term precursor can refer to a compound that participates in the chemical reaction that produces another compound, and particularly to a compound that constitutes a film matrix or a main skeleton of a film, whereas the term reactant can refer to a compound, in some cases other than precursors, that activates a precursor, modifies a precursor, or catalyzes a reaction of a precursor; a reactant may provide an element (such as Si, Ge, C, O, H and/or N) to a film matrix and become a part of the film matrix. In some cases, the terms precursor and reactant can be used interchangeably. The term inert gas refers to a gas that does not take part in a chemical reaction to an appreciable extent and/or a gas that excites or cleaves a precursor when, for example, RF or microwave power is applied to form a plasma, but unlike a reactant, the inert gas (or species thereof) may not become a part of a film matrix to an appreciable extent.

The term cyclic deposition process or cyclical deposition process may refer to the sequential introduction of precursors and/or reactants into a reaction chamber and/or sequential application of plasma power to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. A cyclical deposition process can include use of activated species (e.g., formed from one or more of precursor(s), reactant(s), or and/or inert gas(es)) that are formed using one or more of a direct plasma, an indirect plasma, and/or a remote plasma.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values (e.g., within ±10, 5, 2, 1, or 0.5%) and include equivalents, and may refer to average, median, representative, majority, etc. in some embodiments. Further, in this disclosure, the terms including, constituted by and having and related words can refer independently to typically or broadly comprising, comprising, consisting essentially of, or consisting of in some embodiments. The term comprising can include examples of consisting essentially of and consisting of. In accordance with aspects of the disclosure, any defined meanings of terms do not necessarily exclude ordinary and customary meanings of the terms.

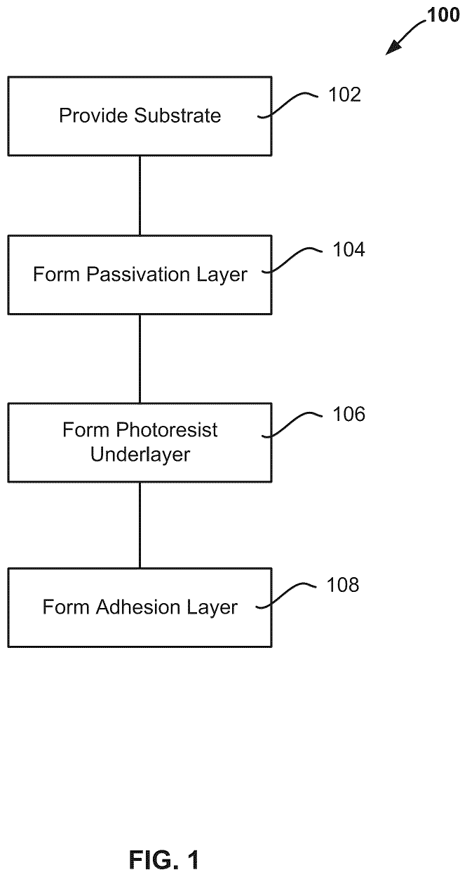

Turning now to the figures, FIG. 1 illustrates a method 100 of forming a structure comprising a photoresist underlayer in accordance with exemplary embodiments of the disclosure. Method 100 includes the steps of providing a substrate (step 102), optionally forming a passivation layer (step 104), forming a photoresist underlayer (step 108), and forming an adhesion layer (step 108).

Step 102 includes providing a substrate comprising a substrate surface, such as a substrate described herein. The substrate can include one or more layers, including one or more material layers, to be etched. By way of examples, the substrate surface can include a deposited oxide, a native oxide, and/or an amorphous carbon layer to be etched and/or a carbon hard mask. The substrate can include several layers underlying the material layer(s) to be etched.

During step 104, a passivation layer is formed. In accordance with examples of the disclosure, the passivation layer is formed between the substrate surface and a subsequently deposited photoresist underlayer. The passivation layer can comprise silicon, germanium, or a mixture thereof.

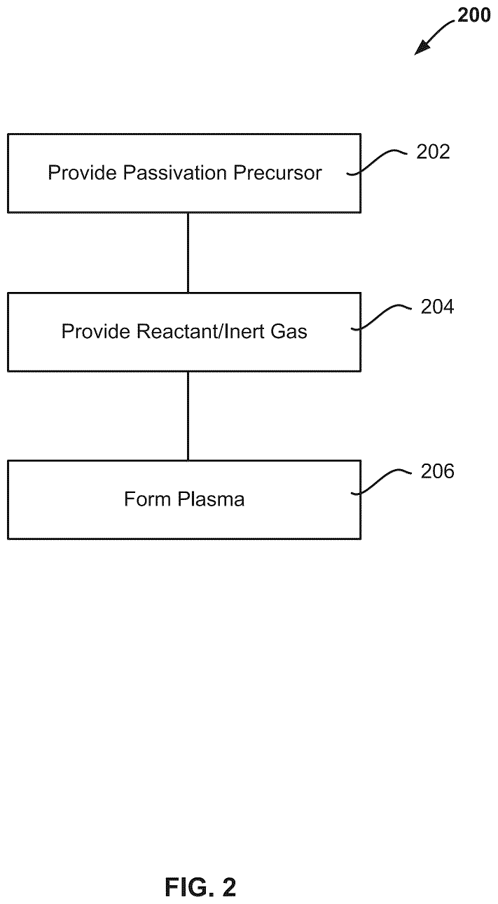

FIG. 2 illustrates an exemplary process 200 suitable for step 104. FIG. 2 illustrates a cyclical process. However, in some cases, step 104 may not be a cyclical process, but rather a CVD process.

Process 200 includes the steps of providing a passivation precursor (step 202), providing a reactant/inert gas (step 204), and forming a plasma (step 206). Steps 202-206 can be repeated a number of times to form the passivation layer. For example, steps 202-206 can be repeated 1 to about 1000 times. A thickness of the passivation layer can be from 1 to 10 nm. A temperature and pressure within a reaction chamber during process 200 can be the same or similar to the temperatures and pressures noted below in connection with process 300/step 106.

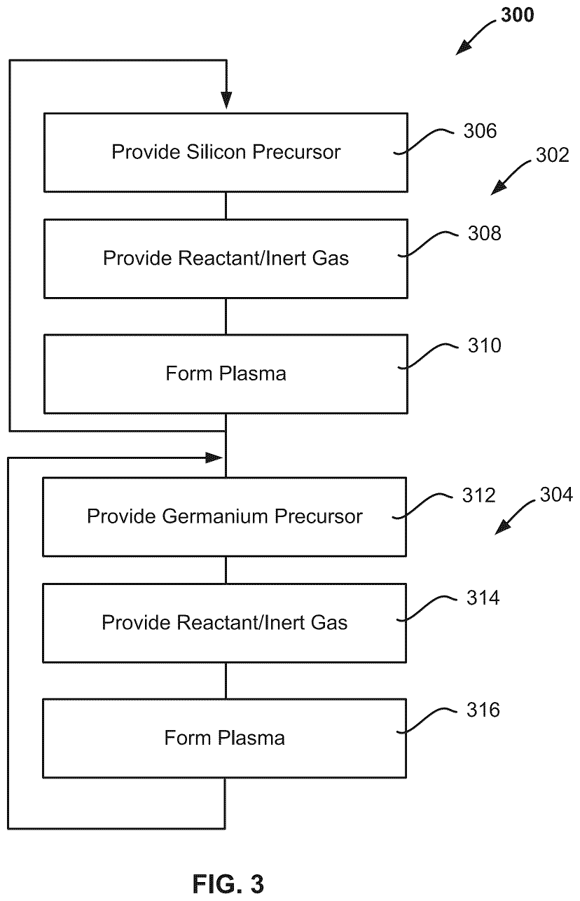

During step 202, the passivation precursor is provided to the reaction chamber. Exemplary passivation precursors suitable for use with step 202 include silicon precursors, germanium precursors, or mixtures thereof. Exemplary silicon precursors and germanium precursors can be the same or similar to those noted below in connection with the process illustrated in FIG. 3. A duration of step 202 can be between about 0.05 and about 5 seconds.

During step 204, a reactant and/or an inert gas is provided to the reaction chamber. Exemplary inert gases and reactants suitable for use with step 204 include Ar, N₂, He, Ne, Kr, Xe, O₂, CO, CO₂, CₓH_{y} (where x and y are integers and x ranges from 1 to 4 and y ranges from 2 to 10), and H₂ or mixtures of any combinations thereof. Step 204 can be continuous through one or more deposition cycles or have a duration of between about 0.05 and about 10 seconds.

During step 206, plasma power is applied to form a plasma from the reactant, inert gas, and/or the passivation precursor. In accordance with examples of the disclosure, steps 202 and 206 do not overlap. In accordance with further examples, steps 204 and 206 overlap. A plasma power during step 206 can be between about 25 and about 500. A duration of step 202 can be between about 0.05 and about 30 seconds.

Referring again to FIG. 1, during step 106, a photoresist underlayer is formed on a surface of the substrate. In accordance with exemplary aspects of method 100, the photoresist underlayer is formed using a (e.g., first) cyclical deposition process—e.g., a plasma-enhanced cyclical deposition process.

In accordance with examples of the disclosure, a temperature within a reaction chamber during step 106 can be (e.g., at or above room temperature and) less than 500° C. A pressure within the reaction chamber during step 106 can be between about 1 Torr and about 20 Torr.

In accordance with exemplary embodiments of the disclosure, step 106 includes forming or depositing a photoresist underlayer that comprises silicon germanium oxide. In accordance with examples of the disclosure, step 106 includes forming one or more of silicon oxide layer using a cyclical deposition process and forming one or more germanium oxide layers using a cyclical deposition process to thereby form a laminate structure, wherein the silicon oxide and the germanium oxide together form the silicon germanium oxide. Alternatively, step 106 can include forming a silicon germanium oxide layer using a cyclical process that includes coflowing a silicon precursor and a germanium precursor to the reaction chamber for a period of time. Deposition cycles can be repeated until a desired silicon germanium oxide film thickness is obtained—e.g., less than 10 nm, less than 5 nm, or greater than 3 nm and less than 10 nm or greater than 0.1 nm and less than 10 nm.

An exemplary cyclical process 300 for forming the photoresist underlayer suitable for step 106 is illustrated in FIG. 3. Cyclical process 300 can include a silicon oxide deposition process (a first cycle 302) and a germanium oxide deposition process (a second cycle 304). Although illustrated with performing cycle 302 prior to performing cycle 304, the method is not so limited. Method 300 can alternatively begin with cycle 304 followed by cycle 302.

In the illustrated example, silicon oxide deposition cycle 302 is a plasma-enhanced cyclical silicon oxide deposition cycle. In particular, silicon oxide deposition cycle 302 includes providing (e.g., pulsing) a silicon precursor into a reaction chamber (step 306), pulsing or continuously providing a reactant (e.g., an oxidant and/or nitriding agent) and/or an inert gas into the reaction chamber (step 308), and forming a plasma (step 310) by providing a plasma power (e.g., to capacitively coupled electrodes within the reaction chamber). Silicon oxide deposition cycle 302 can also include purging the reaction chamber after one or more steps 306-310. During purge steps, any excess precursor and/or reactants and/or any reaction byproducts can be purged from the reaction chamber. The purge can be performed by supplying an inert gas and/or non-activated reactant to the reaction chamber and/or using a vacuum source. Cycle 302 can be repeated—e.g., between about 1 and about 200 times, before process 300 proceeds to step cycle 304.

A precursor comprising silicon (silicon precursor) is provided during step 306. In some cases, the silicon precursor also includes carbon. In some cases, silicon precursor is nitrogen-free. In some cases, the silicon precursor includes nitrogen.

In accordance with further examples, the silicon precursor comprises, consists of or consists essentially of Si, C, H, and O, or Si, C, H, O, and N. The silicon precursor may be provided to the reaction chamber with the aid of a carrier gas, such as an inert gas.

By way of particular examples, the silicon precursor can be selected from one or more of the group consisting of:

In accordance with further examples, the silicon precursor is selected from one or more of the group consisting of: 3-methoxypropyltrimethoxysilane, bis(trimethoxysilyl) methane, 1,2-bis(methyldimethoxysilyl)ethane, 1,2-bis(triethoxysilyl)ethane, 1,2-bis(triethoxysilyl) ethene, 1,2-bis(diethoxymethylsilyl)ethane, 1,2-bis(trimethoxysilyl)ethane, 1,1,3,3-tetramethoxy-1,3-disilacyclobutane, 1,1,3,3-tetraethoxy-1,3-disilacyclobutane, 1,1,3,3,5,5-hexamethoxy-1,3,5-trisilacyclohexane, 1,1,3,3,5,5-hexaethoxy-1,3,5-trisilacyclohexane, and 3-(trimethoxysilyl) propylamine.

A flowrate of the silicon precursor during step 306 can be between about 0.1 slm and 10 slm. A duration of step 306 (e.g., of a pulse within a cycle) can be between about 0.1 s and about 1 s. In accordance with examples of the disclosure, the silicon precursor used during process 200 (step 104) is the same as the silicon precursor used during process 300 (step 106). In other cases, the silicon precursors can be different.

During step 308, a reactant is provided to the reaction chamber. The provision of the reactant during step 308 can be continuous through process 302 or can be pulsed. In accordance with examples of the disclosure, the reactant is an oxidizing reactant, a nitriding reactant, or a reducing agent, such as a hydrogen-containing reactant. The oxidizing and/or nitriding reactant can include reactants that include one or more of oxygen and nitrogen. In some cases, the reactant can include both nitrogen and oxygen. And, in some cases, two or more oxidizing and/or nitriding reactants can be included in a single pulse or in a continuous flow. Exemplary oxidizing and nitriding agents include oxygen (O₂), water (H₂O), ozone (O₃), hydrogen peroxide (H₂O₂), ammonia (NH₃), diazene (N₂H₂), CO₂, nitrous oxide (N₂O); exemplary hydrogen-containing reactants include hydrogen (H₂), and the like.

The oxidizing and/or nitriding reactant can be exposed to a (e.g., direct) plasma during step 310 to form excited species for use in a PEALD process or cyclical plasma process. A power to form the plasma during step 310 can be about 25 W to about 500 W. A frequency of the power to form the plasma can be between about 200 kHz and about 2.45 GHz. A duration of step 310 can be between about 0.1 and about 30 seconds.

In the illustrated example, germanium oxide deposition process/second cycle 304 includes a plasma-enhanced cyclical germanium oxide deposition cycle. In particular, germanium oxide deposition cycle 304 includes providing (e.g., pulsing) a germanium precursor comprising germanium into a reaction chamber (step 312), pulsing or continuously providing a reactant (e.g., an oxidant and/or nitriding agent) and/or an inert gas into the reaction chamber (step 314), and forming a plasma (step 316) by providing a plasma power. Germanium oxide deposition cycle 304 can also include purging the reaction chamber after one or more steps 312-316. As noted above, during purge steps, any excess precursor and/or reactants and/or any reaction byproducts can be purged from the reaction chamber. The purge can be performed by supplying an inert gas and/or non-activated plasma to the reaction chamber and/or using a vacuum source. Germanium oxide deposition cycle 304 can be repeated—e.g., between about 1 and about 200 or about 100 and about 200 times, before method 100 proceeds to step 108 or before process 300 returns to step 306.

A precursor comprising germanium (germanium precursor) is provided during step 312. In accordance with examples of the disclosure, the germanium precursor comprises, consists of or consists essentially of Ge, C, H, and O, or Ge and X or Ge, X, C, H, and O, or Ge, X, C, H, and N, where X represents a halogen. The germanium precursor may be provided to the reaction chamber with the aid of a carrier gas.

Exemplary germanium precursors that are suitable for use during step 312 include one or more of a germanium halide compound, a germanium amino compound, or an organogermanium compound. Particular exemplary germanium precursors include GeCl₄, GeBr₄, GeI₄, Me₂GeCl₂, Me₃Ge—Cl, Me₄G, EtGeCl, Et₂GeCl₂, Et₃GeC, Et₃Ge—H, (ⁱBu) GeH₃, Me₃Ge—GeMe₃, (MeO)₄Ge, (EtO)₄Ge, (ⁱPrO)₄Ge, H₃Ge—GeH₃, and Ge[(CH₃)₂N]₄ where Me represents a methyl group, Et represents an ethyl group, iBu represents an isobutyl group, and iPr represents an isopropyl group.

A flowrate of the germanium precursor during step 312 can be between about 0.1 and 10 slm. A duration of step 312 (e.g., of a pulse within a cycle) can be between about 0.1 s and about 1 s.

During step 314, a reactant and/or an inert gas is provided to the reaction chamber. Step 314 can be the same as or similar to step 308 described above. The reactant provided during step 308 and during step 314 can be the same or different.

Similarly, step 316 can be the same or similar to step 310. For example, the plasma power and the duration of step 317 can be as described above in connection with step 310. The power levels and/or durations of steps 316 and 310 can be the same or different.

Referring again to FIG. 1, once the photoresist underlayer is formed, an adhesion layer is formed during step 108. The adhesion layer can be formed overlying and in contact with the photoresist underlayer formed during step 106. Step 108 can be performed in situ-within the same reaction chamber and without an air and/or a vacuum break. In other cases, the adhesion layer can be formed in another reaction chamber after a vacuum break. In other words, the bulk layer can be formed in one reaction chamber. Then, the substrate can be transferred from the reaction chamber to another reaction chamber through wafer transfer chamber. A vacuum break can occur when transferring the substrate between reaction chambers.

In accordance with examples of the disclosure, the adhesion layer comprises silicon, carbon, and hydrogen and one or more of oxygen or nitrogen. In some cases, the adhesion layer may additionally or alternatively comprise a germanium carbon layer and/or a germanium oxide layer.

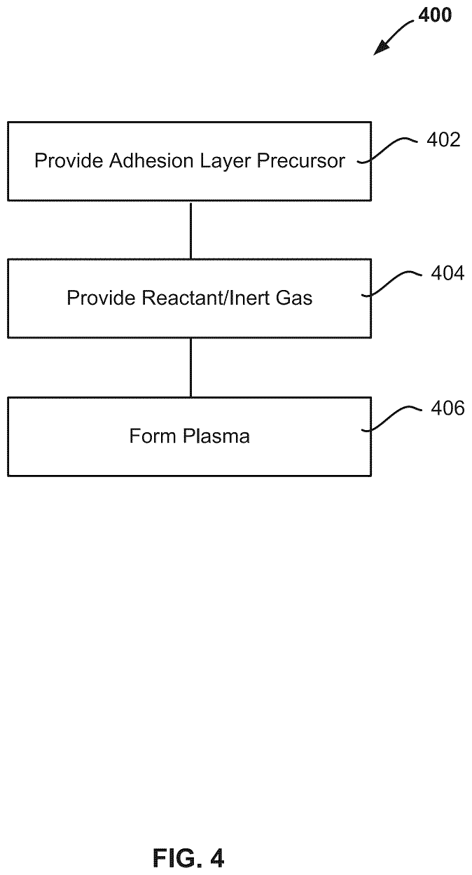

FIG. 4 illustrates an exemplary cyclical deposition process 400 for forming an adhesion layer. Cyclical deposition process 400 includes pulsing or providing an adhesion layer precursor (e.g., a silicon precursor) to a reaction chamber (step 402), optionally purging any unreacted precursor and/or byproducts, providing one or more of an inert gas and a reactant gas into the reaction chamber (step 404), and forming a plasma to form activated species that react with the adhesion layer precursor or a derivative thereof to form the adhesion layer (step 406), and optionally purging any excess reactive species and/or byproducts from the reaction chamber. Steps 402-406 can be repeated—e.g., between about 1 and about 500 or about 50 or about 60 or about 70 and about 120 times. A temperature and pressure during step 108 can be the same or similar as the temperature and pressure for steps 102-106.

During step 402, an adhesion layer precursor—e.g., a silicon precursor and/or a germanium precursor, is provided to the reaction chamber. The silicon precursor and the germanium precursor can include any of the silicon precursors and/or germanium precursors noted above in connection with process 300.

During step 404, a reactant and/or an inert gas is provided to the reaction chamber. The inert gas can be or include one or more of Ar, He, Ne, Kr, and Xe. The inert and/or a reactant gas can be or include one or more of Ar, He, Ne, Kr, Xe, O₂, CO, CO₂, CₓH_{y} (as defined above), and H₂ or any mixture thereof. The reactant gas can be or include N₂, N₂O, NH₃ or any mixture thereof. A flowrate of the one or more of an inert gas and a nitrogen-containing reactant gas can be between about 5 and about 100 sccm or between about 0.1 and about 10 slm.

During step 406, a plasma is formed using the inert gas and/or a reactant provided during step 404. A power to form the plasma during step 406 can be about 30 W to about 1000 W. A duration of step 406 can be between about 0.1 s and about 2 s. A frequency of the power to form the plasma can be between about 200 kHz and about 2.45 GHz.

At the end of step 406, the plasma power is switched off and any excess reactive species and/or byproducts are purged. Steps 402-406 can be repeated a number of times to form a silicon-based adhesion layer of a desired thickness—e.g., greater than 0 and less than about 2 nm.

A composition of a silicon germanium oxide underlayer formed according to process 300 can be manipulated by, for example, adjusting a number of silicon oxide deposition cycles 302 relative to a number of germanium oxide deposition cycles 304 and/or by selection of silicon and germanium precursors and/or by adjusting flowrates of the respective precursors and/or the like. In some applications, it may be desirable to have a germanium concentration in the silicon germanium oxide underlayer between about 1 and about 10 or between about 10 and about 30 at %, to enable desired adhesion to a photoresist layer, without use of an undesirably thick adhesion layer. Silicon germanium oxide underlayers with such germanium concentrations may be particularly desirable for line formation processes to mitigate line-edge and line-width roughness (LER/LWR) during formation of the lines. In other cases, such as via formation applications, adhesion may be of less concern and scum formation may be of concern. In these cases, an amount of germanium in the silicon germanium oxide underlayer can be greater than 20 or between about 20 and about 50 or between about 5 and about 20 at %.

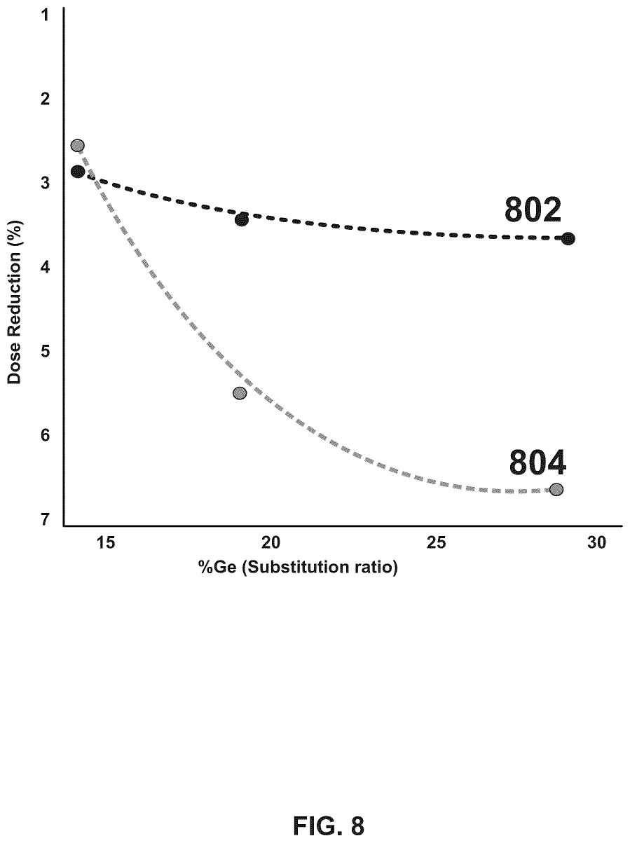

FIG. 8 illustrates CAR dose reduction as a function of germanium concentration in a silicon germanium oxide underlayer for data 802 representing samples having a first adhesion layer and data 804 representing samples having a second adhesion layer. As illustrated, a dose amount generally decreases with an increasing amount of germanium in the silicon germanium oxide underlayer for both sets of data.

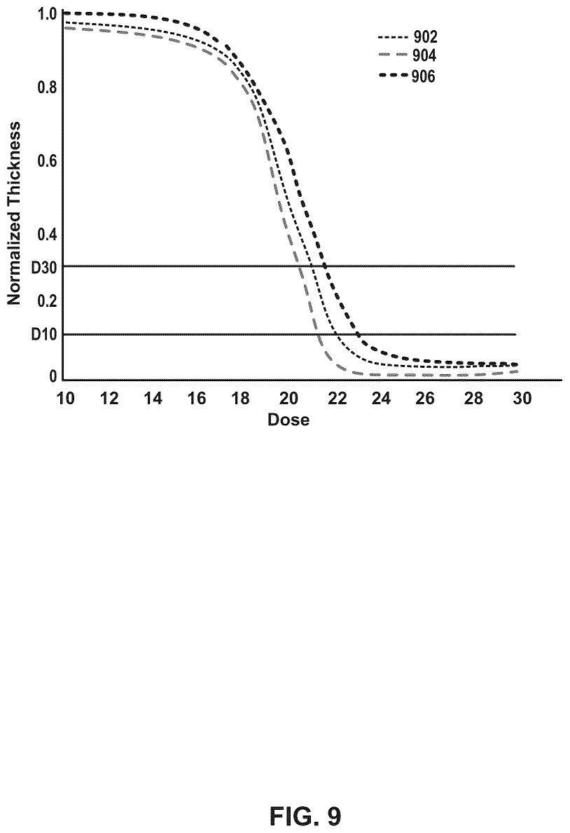

FIG. 9 illustrates normalized adhesion data versus CAR dose for data 902 representing a first adhesion layer, data 904 representing a second adhesion layer, and data 906 representing a reference layer. A concentration of germanium in the silicon germanium oxide underlayer for both sets of data 902 and 904 was about the same (˜18 at %) for a same number of cycles (50). The data in FIG. 9 show that increased adhesion layer thickness can hinder dose reduction of the silicon germanium oxide underlayer. Further, increased Ge concentration in the underlayer appears to hinder growth of the adhesion layer.

The data in FIGS. 8 and 9 indicate that for dose reduction, higher germanium concentrations and lower adhesion layer thicknesses may be desirable. However, these conditions can lead to pattern collapse—e.g., during the formation of lines.

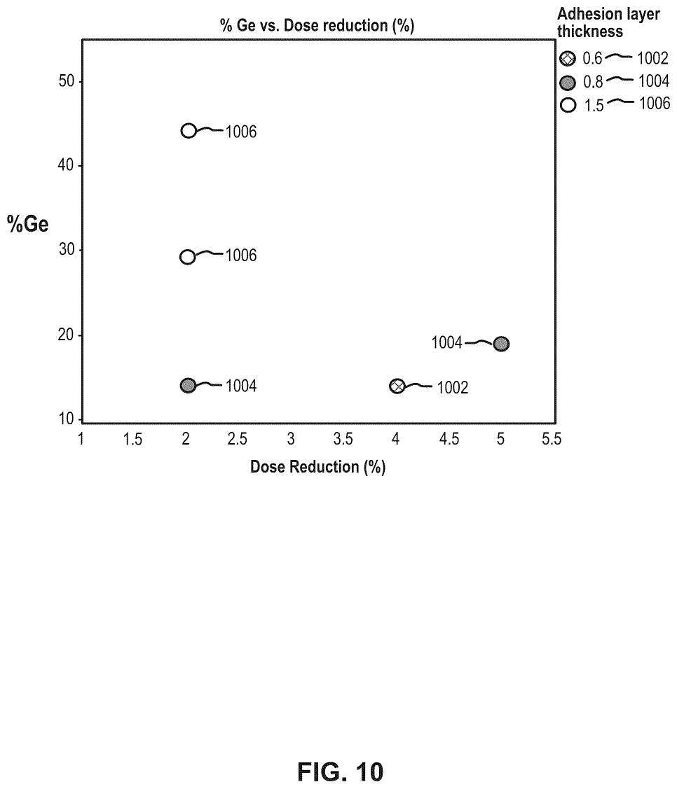

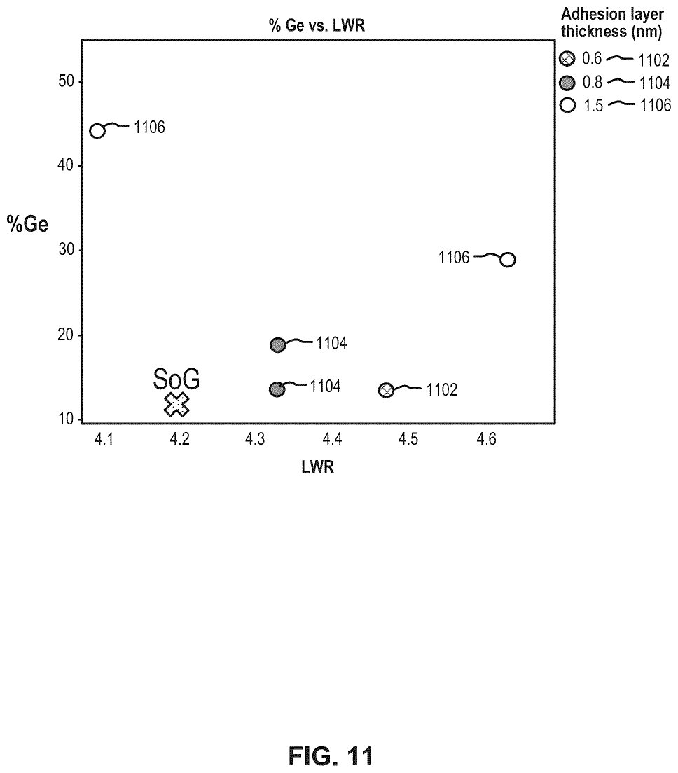

FIGS. 10 and 11 illustrate data for various adhesion layer thicknesses: 1002 and 1102 represent a thickness of 0.6 nm, 1004 and 1104 represent a thickness of 0.8 nm and 1006 and 1106 represent a thickness of 1.5 nm. FIG. 10 illustrates dose reduction as a function of germanium concentration in the silicon germanium oxide underlayer for the variable adhesion layer thicknesses. FIG. 11 illustrates germanium concentration versus LWR for the variable adhesion layer thicknesses.

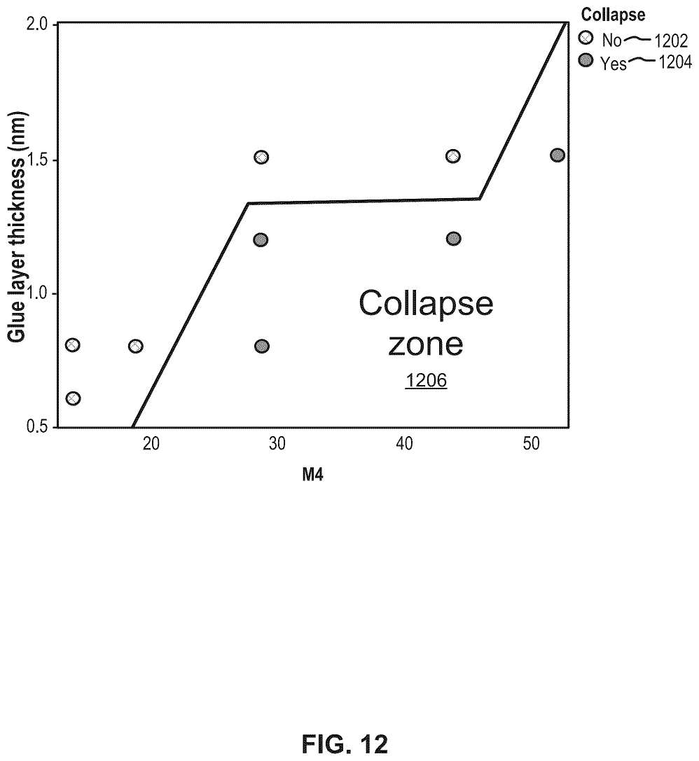

FIG. 12 illustrates data 1202 corresponding to no line collapse and data 1204 corresponding to line collapse. As illustrated, for these particular examples, when an amount of germanium in the silicon germanium oxide underlayer increases, an adhesion layer thickness to mitigate collapse also increases. FIG. 12 illustrates a collapse zone 1206 for a particular line formation process.

In the cases illustrated in FIGS. 8-12, a target dose reduction of about 5% is desirable to reduce dose, while maintaining desired LWR. In this case, a germanium concentration in the silicon germanium oxide underlayer can be between about 5 and about 20 or between about 10 and about 50.

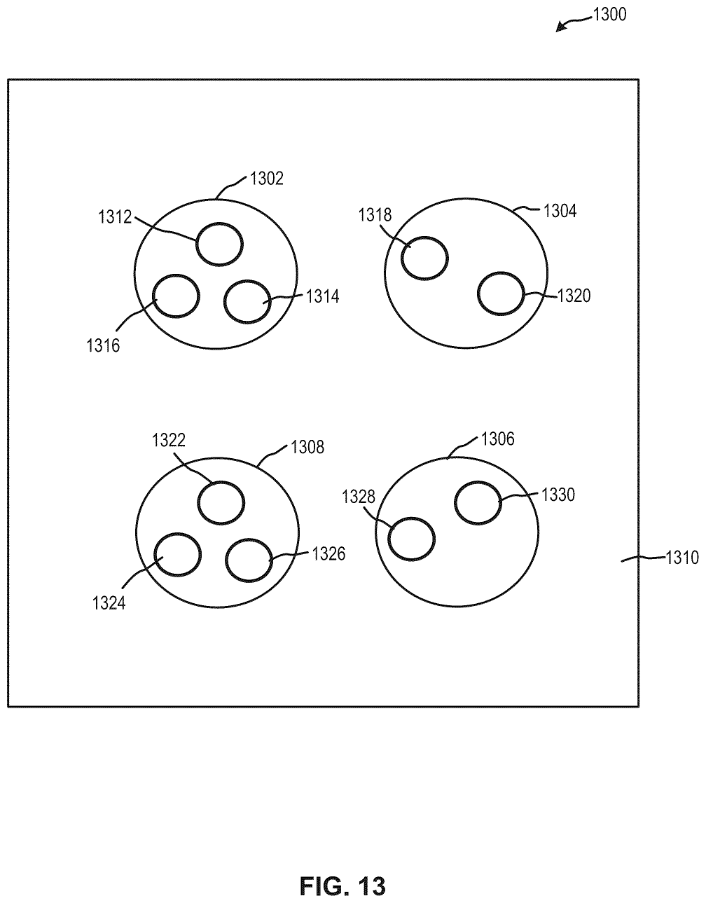

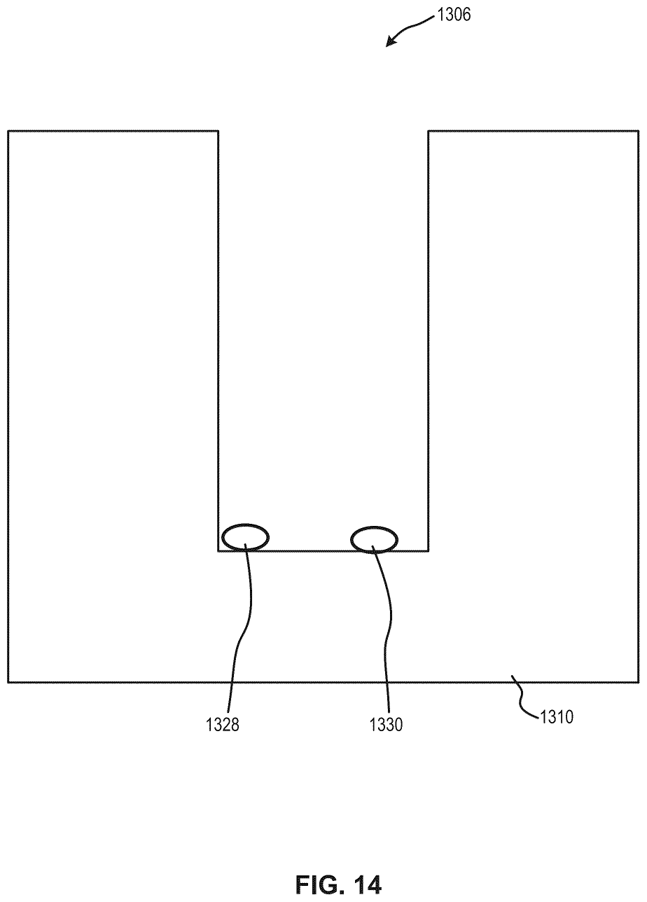

As noted above, in other applications, such as via or hole formation processes, adhesion of photoresist may not be as important as it is in line formation processes. FIG. 13 illustrates a top view of a structure 1300 that has a plurality of vias 1302-1308 formed within a material layer 1310. FIG. 14 illustrates a cross-sectional view of via 1306. In some cases, scum 1312-1330 (e.g., photoresist residue) can remain in vias 1302-1308 after vias 1302-1308 are formed. Increasing an amount of germanium in the silicon germanium oxide underlayer can mitigate scum formation. In accordance with examples of the disclosure, a germanium concentration in the silicon germanium oxide underlayer can be between about 20 to about 50 or between about 5 to about 20. Such germanium concentrations can mitigate scum formation in vias during via formation.

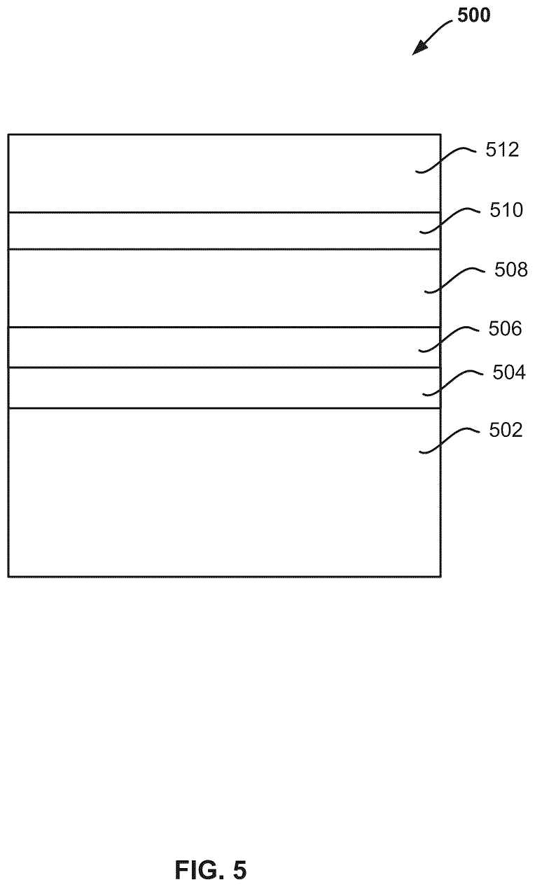

FIG. 5 illustrates a structure 500 in accordance with exemplary embodiments of the disclosure. Structure 500 can be formed using, for example, method 100.

As illustrated, structure 500 includes a substrate 502, a material layer 504, a passivation layer 506, photoresist underlayer 508, a photoresist layer 512, and an adhesion layer 510 interposed between and in contact with photoresist underlayer 508 and photoresist layer 512.

Substrate 502 can include a substrate as described above. By way of examples, substrate 502 can include a semiconductor substrate, such as a bulk material, such as silicon (e.g., single-crystal silicon), other Group IV semiconductor material, Group III-V semiconductor material, and/or Group II-VI semiconductor material and can include one or more layers (e.g., a patterning stack) overlying the bulk material. Further, as noted above, substrate 502 can include various topologies, such as recesses, lines, and the like formed within or on at least a portion of a layer of the substrate.

Material layer 504 can be patterned and etched using a photoresist underlayer and a layer of photoresist as described herein. Exemplary materials suitable for material layer 504 include, for example, oxides, such as native oxides or field oxides. Other exemplary material layer 504 materials include a carbon hard mask, amorphous carbon, nitrides, other oxides, silicon, and add-on films (e.g., a self-assembled monolayer (e.g., hexamethyldisilazane (HMDS)).

Passivation layer 506 is interposed between material layer 504 (e.g., a carbon hard mask layer) and the photoresist underlayer 508. Passivation layer 506 can include, for example, silicon, germanium, and oxygen. Passivation layer 506 can be formed using, for example, process 200/step 104.

Photoresist underlayer 508 can include a photoresist underlayer formed in accordance with a method described herein (e.g., method 100/process 300) and/or have properties, compositions, and/or material as described herein. Photoresist underlayers include silicon germanium oxide, which may be laminar or unitary. In accordance with examples of the disclosure, an amount of germanium, silicon, and/or oxygen in the silicon germanium oxide can vary along a depth of photoresist underlayer 508. Further, an amount of germanium in the film can be tuned for desired application—e.g., to control dose reductions without adversely affecting etch selectivity to an underlying layer. For example, as noted above, a germanium concentration in the silicon germanium oxide underlayer can be between about 10 and about 50 or between about 1 and about 10 at %, to enable desired adhesion to a photoresist layer, without use of an undesirably thick adhesion layer, or can be greater than 20 or between about 20 and about 50 or between about 5 and about 20 at % to mitigate scum formation in vias.

A thickness of photoresist underlayer 508 can depend on a composition of material layer 504, a thickness of material layer 504, a type of photoresist, application (e.g., line or via formation), and the like. In accordance with examples of the disclosure, photoresist underlayer 508 has a thickness of less than 10 nm or less than or about 5 nm or is greater than 0.1 nm and less than 10 nm. If photoresist underlayer 508 is too thick, residual underlayer material may remain after an etch step. If photoresist underlayer 508 is too thin, photoresist underlayer 508 may not provide desired pattern transfer during an etch process.

Adhesion layer 510 is interposed between and in contact with photoresist underlayer 508 and the photoresist layer 512. Adhesion layer 510 desirably exhibits good adhesion and other properties as described herein. As noted above, in accordance with examples of the disclosure, adhesion layer 510 can, in some cases, include nitrogen, carbon, and/or oxygen. In accordance with examples of the disclosure, the adhesion layer comprises silicon and/or germanium, carbon, and hydrogen and one or more of oxygen or nitrogen. A thickness of the adhesion layer can be greater than 0 nm and less than 2 nm.

Photoresist layer 512 is formed overlying photoresist underlayer 508 and adhesion layer 510. Photoresist layer 512 can be or include positive or negative tone (e.g., EUV (e.g., CAR)) photoresist.

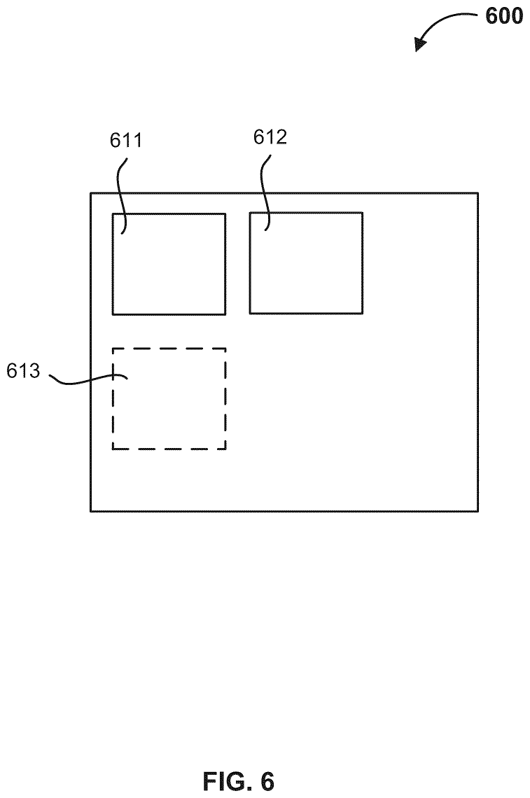

FIG. 6 illustrates a system 600 configured for executing a method as described herein. System 600 comprises at least one reaction chamber which is configured for depositing an underlayer and/or forming an adhesion layer as described herein. System 600 may comprise a first reaction chamber 611 and a second reaction chamber 612 that may both be configured for depositing an underlayer and forming an adhesion layer as described herein, or a part thereof. If desired, system 600 can include a third reaction chamber 613 in which another process, such as a thermal or plasma-enhanced post treatment, may be carried out.

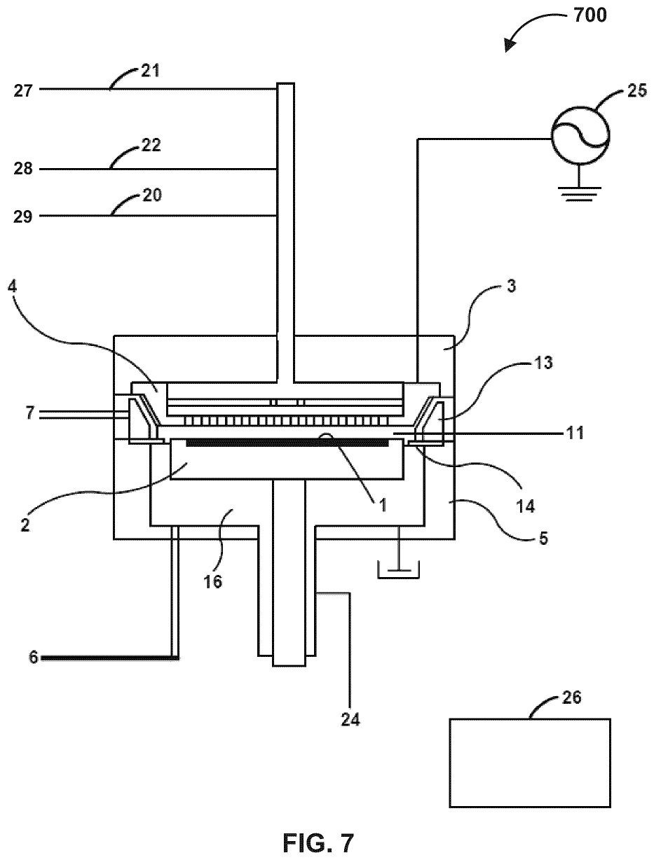

FIG. 7 illustrates an exemplary reaction system that includes a chamber suitable for use as reaction chamber 611 or 612. Reactor system 700 can be used to perform one or more methods or processes as described herein and/or to form one or more structures or portions thereof as described herein.

Reactor system 700 includes a pair of electrically conductive flat-plate electrodes 4, 2 in parallel and facing each other in the interior 11 (reaction zone) of a reaction chamber 3. A plasma can be excited within reaction chamber 3 by applying, for example, HRF power (e.g., 13.56 MHz or 27 MHz) from power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. Electrode 4 can serve as a gas distribution device, such as a shower plate. Reactant gas, dilution gas, if any, precursor gas, and/or the like can be introduced into reaction chamber 3 using one or more of a gas line 20, a gas line 21, and a gas line 22, respectively, and through the shower plate 4. Although illustrated with three gas lines, reactor system 700 can include any suitable number of gas lines. Gas line 20 can be coupled to a silicon precursor source 29, gas line 21 can be coupled to an inert gas source 27, and gas line 22 can be coupled to another (e.g., reactant and/or germanium) gas source 28.

In reaction chamber 3, a circular duct 13 with an exhaust line 7 is provided, through which gas in the interior 11 of the reaction chamber 3 can be exhausted. Additionally, a transfer region 5, disposed below the reaction chamber 3, is provided with a seal gas line 24 to introduce seal gas into the interior 11 of the reaction chamber 3 via the interior 16 (transfer zone) of the transfer region 5, wherein a separation plate 14 for separating the reaction zone and the transfer zone is provided (a gate valve through which a wafer is transferred into or from the transfer region 5 is omitted from this figure). The transfer region is also provided with an exhaust line 6. In some embodiments, the deposition and treatment steps are performed in the same reaction space, so that two or more (e.g., all) of the (e.g., passivation, underlayer, and adhesion layer) steps can continuously be conducted without exposing the substrate to air or other oxygen-containing atmosphere.

In some embodiments, continuous flow of an inert or carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching between the main line and the detour line, without substantially fluctuating pressure of the reaction chamber.

Reactor system 700 also includes one or more controller(s) 26 programmed or otherwise configured to cause one or more method steps as described herein to be conducted. Controller(s) 26 are communicated with the various power sources, heating systems, pumps, robotics and gas flow controllers, or valves of the reactor, as will be appreciated by the skilled artisan. By way of examples, controller 26 can be configured to control gas flow of a silicon precursor and an inert gas to form an adhesion layer on a photoresist underlayer. Additionally or alternatively, the controller can be configured to perform steps to form a photoresist underlayer as described herein.

In some embodiments, a dual chamber reactor (two sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

We claim:

1. A method of forming a structure comprising a photoresist underlayer, the method comprising the steps of:
providing a substrate comprising a substrate surface within a reaction chamber; and
using a first cyclic deposition process, forming a photoresist underlayer overlying the substrate surface,
wherein the photoresist underlayer comprises silicon germanium oxide.

2. The method according to claim 1, wherein the method further comprises forming a passivation layer between the substrate surface and the photoresist underlayer.

3. The method according to claim 2, wherein the step of forming the passivation layer comprises providing a passivation precursor, providing a reactant and/or an inert gas, and forming a plasma.

4. The method according to claim 1, wherein the first cyclic deposition process comprises coflowing a silicon precursor and a germanium precursor to the reaction chamber for a period of time.

5. The method according to claim 1, wherein the first cyclic deposition process comprises a first cycle to deposit silicon oxide overlying the substrate surface and a second cycle to deposit germanium oxide overlying the substrate surface, wherein the silicon oxide and the germanium oxide together form the silicon germanium oxide.

6. The method according to claim 5, wherein the first cycle comprises a plasma-enhanced cyclical silicon oxide deposition cycle.

7. The method according to claim 6, wherein the plasma-enhanced cyclical silicon oxide deposition cycle comprises:
providing a silicon precursor to the reaction chamber;
providing a reactant to the reaction chamber; and
providing a plasma power to form a plasma using the reactant.

8. The method according to claim 7, wherein the silicon precursor comprises Si, C, H, and O or Si, C, H, O, and N.

9. The method according to claim 5, wherein the second cycle comprises a plasma-enhanced cyclical germanium oxide deposition cycle.

10. The method according to claim 9, wherein the plasma-enhanced cyclical germanium oxide deposition cycle comprises:
providing a germanium precursor to the reaction chamber;
providing a reactant to the reaction chamber; and
providing a plasma power to form a plasma using the reactant.

11. The method according to claim 10, wherein the germanium precursor comprises one or more of a germanium halide compound, a germanium amino compound, or an organogermanium compound.

12. The method according to claim 1, further comprising a step of forming an adhesion layer overlying and in contact with the photoresist underlayer.

13. The method according to claim 12, wherein the step of forming the adhesion layer comprises:
providing the silicon precursor to the reaction chamber;
providing one or more of an inert gas and a reactant gas into the reaction chamber; and
forming a plasma to form activated species that react with the silicon precursor or a derivative thereof to form the adhesion layer,
wherein the adhesion layer comprises silicon, carbon, and hydrogen and one or more of oxygen and nitrogen.

14. A structure comprising:
a substrate;
a photoresist underlayer comprising silicon germanium oxide overlying the substrate; and
a photoresist layer overlying the photoresist underlayer.

15. The structure according to claim 14, wherein the substrate comprises a carbon hard mask layer.

16. The structure according to claim 14, wherein the structure further comprises a passivation layer between the carbon hard mask layer and the photoresist underlayer.

17. The structure according to claim 14, further comprising an adhesion layer interposed between and in contact with the photoresist underlayer and the photoresist layer.

18. The structure according to claim 17, wherein the adhesion layer comprises silicon, carbon, and hydrogen and one or more of oxygen and nitrogen.

19. The structure according to claim 14, wherein a thickness of the photoresist underlayer is greater than 0.1 nm and less than 10 nm.

20. The structure according to claim 14, wherein a thickness of the adhesion layer is greater than 0 nm and less than 2 nm.
